(19) United States
(12) Patent Application Publication
(10) Pub. No.: US 2021/0364859 A1
(43) Pub. Date: Nov. 25, 2021

(54) LUMINOUS FLUX CONTROL MEMBER, LIGHT-EMITTING DEVICE, PLANAR LIGHT SOURCE DEVICE, AND DISPLAY DEVICE

(71) Applicant: ENPLAS CORPORATION, Saitama (JP)

(72) Inventors: Toshihiko MOCHIDA, Saitama (JP); Hiroshi TAKATORI, Saitama (JP); Takao MIYOSHI, Saitama (JP)

(21) Appl. No.: 16/479,644

(22) PCT Filed: Jan. 12, 2018
(86) PCT No.: PCT/JP2018/000634

§ 371 Date: Jul. 22, 2019

(30) Foreign Application Priority Data
Jan. 23, 2017 (JP) 2017-009401

(51) Int. Cl. G02F 1/1335; G02B 13/18; G02F 1/13357

(52) U.S. Cl. CPC G02F 1/133607; G02F 1/133603; G02B 13/18

(57) ABSTRACT

A luminous flux control member has: an incident surface, an emission surface; a back surface; and a plurality of recessed or projecting first quadrangular pyramid parts placed in grid form on at least a portion of the back surface. The first quadrangular pyramid part includes: a first inclined plane that is inclined so as to face the back side as separation increases from the central axis; a second inclined plane that is inclined so as to face the front side as separation increases from the central axis; and a connecting part that connects the first inclined plane and the second inclined plane. In a cross section including the central axis and the center of the connecting part, the first inclined plane is larger than the second inclined plane.

### TECHNICAL FIELD

The present invention relates to a light flux controlling member, a light emitting device, a surface light source device and a display device.

### BACKGROUND ART

Some transmission type image display apparatuses such as liquid crystal display apparatuses use a direct surface light source device as a backlight. In recent years, direct surface light source devices having a plurality of light emitting elements as the light source have been used.

For example, a direct surface light source device includes a substrate, a plurality of light emitting elements, a plurality of light flux controlling members and a light diffusion member. Each of the light emitting elements is, for example, a light-emitting diode (LED) such as a white light-emitting diode. The light emitting elements are disposed on the substrate in a lattice. The light flux controlling member that spreads the light of the light emitting element in the surface direction of the substrate is disposed over each light emitting element. The light emitted from the light flux controlling member is diffused by the light diffusion member so as to illuminate an illumination target member (for example, a liquid crystal panel) in a planar fashion (see, for example, PTL 1).

FIG. 1 illustrates a configuration of conventional light emitting device 10 disclosed in PTL 1. FIG. 1A illustrates light paths in a cross section of conventional light emitting device 10, and FIG. 1B illustrates light paths in a cross section of another conventional light emitting device 20.

As illustrated in FIG. 1A, light emitting device 10 includes light emitting element 11 and light flux controlling member 12. Light flux controlling member 12 includes incidence surface 13 and emission surface 14. Incidence surface 13 is an inner surface of a recess disposed opposite the light-emitting surface of light emitting element 11, and receives light emitted from light emitting element 11. Emission surface 14 emits, to the outside, light entered from incidence surface 13.

As illustrated in FIG. 1A, light emitted from light emitting element 11 enters light flux controlling member 12 from incidence surface 13, and reaches emission surface 14. A majority of the light reaching emission surface 14 is emitted to the outside from emission surface 14 (see the solid arrow). A part of the light reaching emission surface 14 is internally reflected toward rear surface 15 of emission surface 14, and reaches rear surface 15. A part of the light reaching rear surface 15 is emitted from rear surface 15 toward substrate 16, and reflected by substrate 16, and is then, entered from rear surface 15 before being emitted from emission surface 14 (see the thick dotted arrow). Another part of the light reaching rear surface 15 is internally reflected by rear surface 15 toward emission surface 14, and is then emitted from emission surface 14 (see the thin dotted arrow).

In this manner, light internally reflected by emission surface 14 becomes light travelling toward a part immediately above light flux controlling member 12, and consequently causes a non-uniform distribution (luminance unevenness) in the luminance of light emitted from light emitting device 10. In addition, when the light reaching rear surface 15 is emitted from rear surface 15, a part of light is absorbed by the substrate, and consequently significant light loss results. In view of this, PTL 1 further provides another light emitting device 20 including another light flux controlling member 22 capable of solving the above-mentioned problem.

As illustrated in FIG. 1B, in other light emitting device 20, annular recess 29 is formed in rear surface 15. Annular recess 29 includes inclined surface 27 inclined so as to come closer to the rear side as the distance thereof from central axis CA increases, and inclined surface 28 disposed inside inclined surface 27 and inclined so as to come closer to the front side as the distance thereof from central axis CA increases. Recess 29 is formed in a region where light internally reflected by emission surface 14 easily reaches.

As illustrated in FIG. 1B, in light emitting device 20, light internally reflected by emission surface 14 reaches a predetermined region where recess 29 is formed in rear surface 15. A part of the light reaching the predetermined region is reflected by inclined surface 27 in a lateral direction, and emitted to the outside.

In addition, PTL 1 discloses rear surface 15 composed of a grain surface. Rear surface 15 composed of the grain surface scatters light internally reflected by emission surface 14 and light directly reaching rear surface 15 from light emitting element 11.

With this configuration, in light emitting device 20 disclosed in PTL 1, light reflected by emission surface 14 does not tend to be directed toward a region right above light flux controlling member 22, or does not tend to be absorbed by substrate 16. In addition, the light reaching rear surface 15 can be scattered. Thus, light emitting device 10 including light flux controlling member 22 disclosed in PTL 1 can uniformly and efficiently emit light in comparison with conventional light emitting device 10 including light flux controlling member 12.

### CITATION LIST

### Patent Literature

PTL 1
Japanese Patent Application Laid-Open No. 2009-043628

### SUMMARY OF INVENTION

### Technical Problem

In the light flux controlling member disclosed in PTL 1, however, a part of light internally reflected by the emission surface reaches inclined surface 27, but another part of the light reaches rear surface 15, and as such, there is a room for improvement in reduction of light that travels toward a region right above the light flux controlling member. In addition, with rear surface 15 composed of the grain surface, a desired distribution of light may not be obtained due to light scattered by the surface although light travelling toward a region right above light flux controlling member can be reduced.

In view of this, an object of the present invention is to provide a light flux controlling member that causes less luminance unevenness due to light internally reflected by the emission surface. In addition, another object of the present invention is to provide a light emitting device, a surface light source device and a display device that include the light flux controlling member.

### Solution to Problem

A light flux controlling member according to the present invention is configured to control a distribution of light emitted from a light emitting element, the light flux controlling member including: an incidence surface that is an inner surface of a recess having an opening on a rear side at a position intersecting a central axis of the light flux controlling member, the incidence surface being configured to allow incidence of light emitted from the light emitting element; an emission surface formed on a front side at a position intersecting a central axis of the light flux controlling member, the emission surface being configured to emit, to outside, the light entered from the incidence surface; a rear surface formed surrounding the opening of the recess; and a plurality of first square pyramid parts disposed in a lattice in at least a part of the rear surface, each of the plurality of first square pyramid parts having a substantially square pyramid shape or a substantially truncated square pyramid shape protruding to the rear side from the rear surface, or recessed to the front side from the rear surface. Each of the plurality of first square pyramid parts includes a first inclined surface, a second inclined surface and a connecting part, the first inclined surface being inclined such that the first inclined surface comes closer to the rear side as a distance thereof from the central axis increases, the second inclined surface being inclined such that the second inclined surface comes closer to the front side as a distance thereof from the central axis increases, the connecting part connecting the first inclined surface and the second inclined surface. In each of the plurality of first square pyramid parts, the first inclined surface is larger than the second inclined surface in a cross section including the central axis and a center of the connecting part.

A light emitting device including: a light emitting element; and the above-mentioned light flux controlling member that is disposed such that the central axis coincides with an optical axis of the light emitting element.

A surface light source device, including: the above-mentioned light emitting device; and a light diffusion member configured to allow light from the light emitting device to pass therethrough while diffusing the light.

A display device, including: the above-mentioned surface light source device; and a display member configured to be irradiated with light emitted from the surface light source device.

### Advantageous Effects of Invention

According to the present invention, it is possible to provide a light flux controlling member that causes less luminance unevenness due to light internally reflected by the emission surface. In addition, it is possible to provide a light emitting device, a surface light source device and a display device that include the light flux controlling member.

### BRIEF DESCRIPTION OF DRAWINGS

FIGS. 1A and 1B illustrate light paths in a cross section of a light emitting device disclosed in PTL 1;

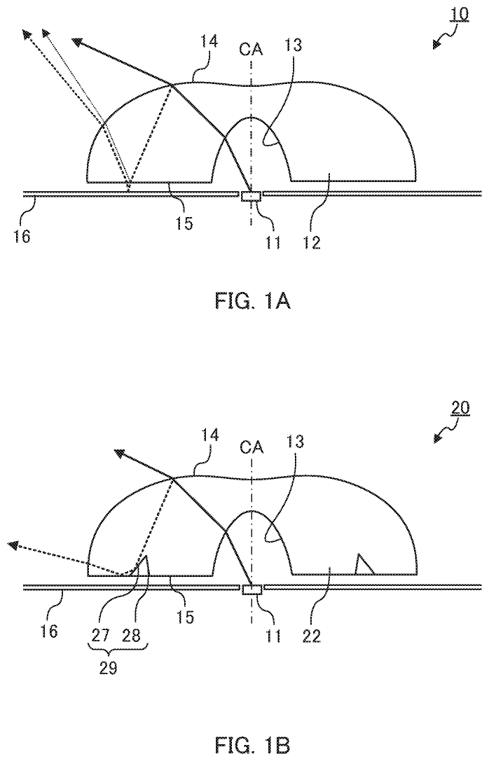

FIGS. 2A and 2B illustrate a configuration of a surface light source device according to Embodiment 1 of the present invention;

FIGS. 3A and 3B are sectional views illustrating a configuration of the surface light source device;

FIG. 4 is a partially enlarged sectional view of the surface light source device;

FIGS. 5A and 5B illustrate a configuration of a light flux controlling member;

FIGS. 6A and 6B are diagrams for describing a first square pyramid part;

FIGS. 7A to 7C illustrate a configuration of a light flux controlling member according to Modification 1;

FIGS. 8A to 8C illustrate a configuration of a light flux controlling member according to Modification 2;

FIGS. 9A and 9B illustrate a configuration of a light flux controlling member of Embodiment 2; and

FIGS. 10A and 10B illustrate a configuration of the light flux controlling member of Embodiment 2.

### DESCRIPTION OF EMBODIMENTS

A light flux controlling member, a light emitting device, a surface light source device and a display device according to embodiments of the present invention are described in detail below with reference to the accompanying drawings. In the following description, as a typical example of the surface light source device according to the embodiments of the present invention, a surface light source device that includes light emitting devices disposed in a lattice and is suitable for a backlight of a liquid crystal display apparatus is described.

### Embodiment 1

### Configurations of Surface Light Source Device and Light Emitting Device

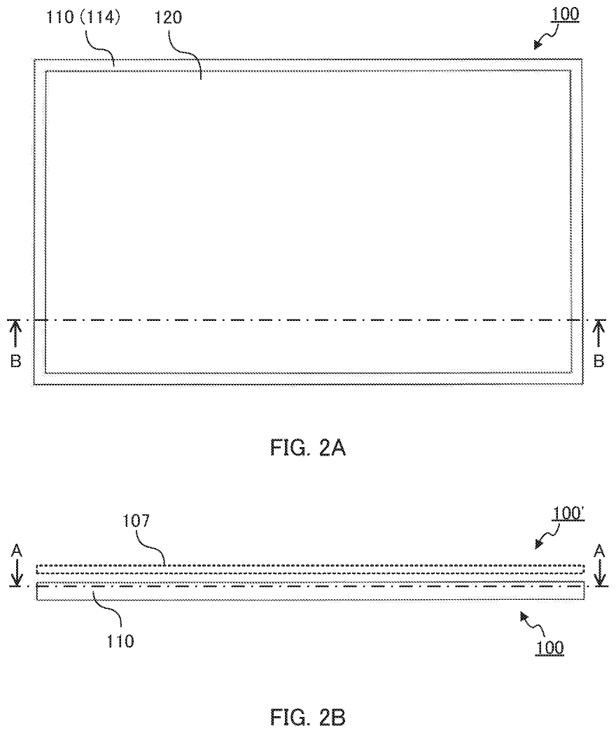

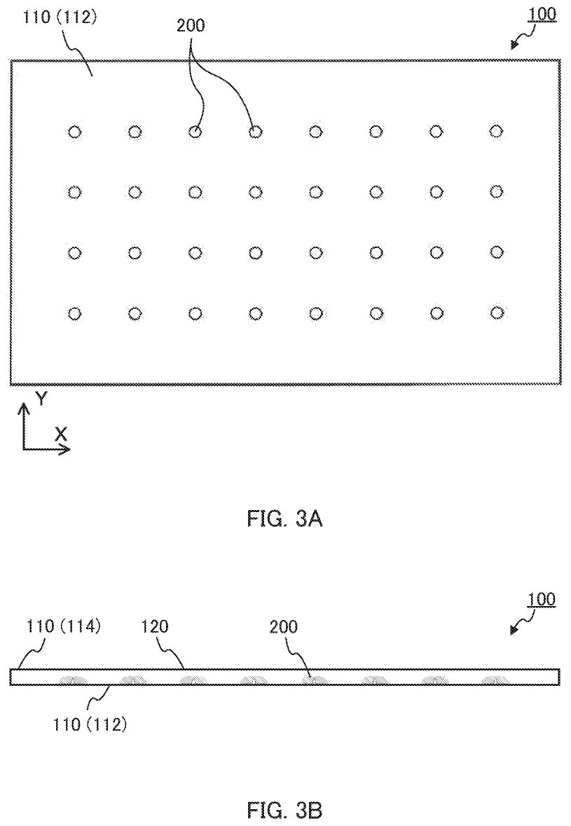

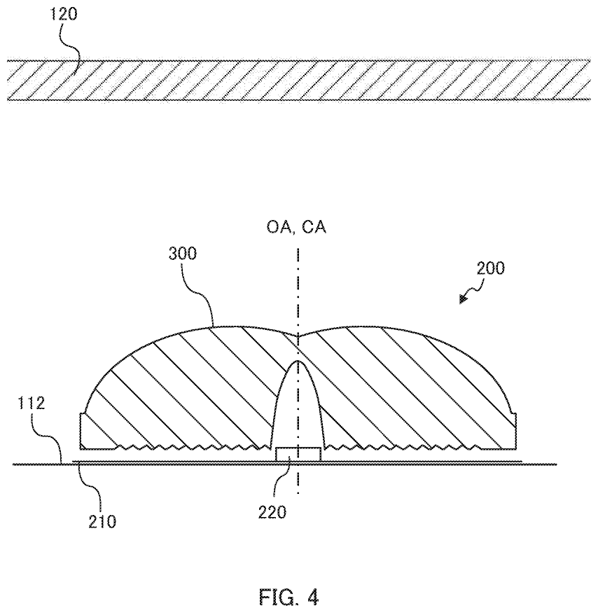

FIGS. 2 to 4 illustrate a configuration of surface light source device 100 according to Embodiment 1 of the present invention. FIG. 2A is a plan view of surface light source device 100 according to Embodiment 1 of the present invention, and FIG. 2B is a front view of surface light source device 100. FIG. 3A is a sectional view taken along line A-A of FIG. 2B, and FIG. 3B is a sectional view taken along line B-B of FIG. 2A. FIG. 4 is a partially enlarged sectional view of surface light source device 100. Note that, in FIG. 4, leg part 360 for fixing light flux controlling member 300 on substrate 210 is omitted.

As illustrated in FIGS. 2A to 4, surface light source device 100 includes housing 110, a plurality of light emitting devices 200, and light diffusion plate (illuminated surface) 120. Surface light source device 100 of the embodiment of the present invention is applicable to a backlight of a liquid crystal display apparatus. In addition, as illustrated in FIG. 2B, surface light source device 100 can be used as display device 100′ when combined with a display member (illumination target member) 107 (indicated with dotted line in FIG. 2B) such as a liquid crystal panel. A plurality of light emitting devices 200 is disposed in a lattice (in the present embodiment, a square lattice) in substrate 210 on bottom plate 112 of housing 110. The inner surface of bottom plate 112 functions as a diffusive reflection surface. In addition, top plate 114 of casing 110 is provided with an opening. Light diffusion plate 120 is disposed to cover the opening, and functions as a light emitting surface. The light emitting surface may have a size of, for example, approximately 400 mm×approximately 700 mm.

A plurality of light emitting devices 200 are disposed on substrate 210 at a predetermined interval. A plurality of substrates 210 are fixed at respective predetermined positions on bottom plate 112 of casing 110. In the present embodiment, light emitting devices 200 are disposed such that the light emission center of each light emitting element 220 (the center of the light-emitting surface) is located in the square lattice. Each light emitting device 200 includes light emitting element 220 and light flux controlling member 300.

Light emitting element 220 is the light source of surface light source device 100, and is mounted on substrate 210. Light emitting element 220 is a light-emitting diode (LED) such as a white light-emitting diode, for example. Light emitting element 220 is disposed such that the light emission center thereof (the center of the light-emitting surface) is located on central axis CA of light flux controlling member 300 (see FIG. 4).

Light flux controlling member 300 is a lens, and is fixed on substrate 210. Light flux controlling member 300 controls the distribution of light emitted from light emitting element 220 such that the light distribution spreads radially outward with respect to central axis CA. Light flux controlling member 300 is disposed over light emitting element 220 in such a manner that central axis CA thereof matches optical axis OA of light emitting element 220 (see FIG. 4). Note that incidence surface 310 and emission surface 320 of light flux controlling member 300 described later are rotationally symmetrical, and the rotation axis thereof coincides with optical axis OA of light emitting element 220. The rotational axes of incidence surface 310 and emission surface 320 are referred to as “central axis CA of light flux controlling member.” In addition, “optical axis OA of light emitting element” refers to a central light beam of a stereoscopic light flux from light emitting element 220.

Light flux controlling member 300 can be formed by integral molding. The material of light flux controlling member 300 is not limited as long as light of a desired wavelength can pass therethrough. For example, the material of light flux controlling member 300 is an optically transparent resin such as polymethylmethacrylate (PMMA), polycarbonate (PC), epoxy resin (EP); and silicone resin, or glass. A main feature of surface light source device 100 according to the present embodiment is the configuration of light flux controlling member 300. Therefore, the configuration of light flux controlling member 300 is described later in detail.

Light diffusion plate 120 is a plate-shaped member having a light diffusing property, and allows the light emitted from light emitting device 200 to pass therethrough while diffusing the light. Light diffusion plate 120 is disposed over light emitting devices 200 approximately in parallel with substrate 210. Normally, the size of light diffusion plate 120 is substantially the same as that of the illumination target member such as a liquid crystal panel. For example, light diffusion plate 120 is formed of an optically transparent resin such as polymethylmethacrylate (PMMA), polycarbonate (PC), polystyrene (PS), and styrene methyl methacrylate copolymerization resin (MS). In order to provide a light diffusing property, minute irregularities are formed on the surface of light diffusion plate 120, or diffusing members such as beads are dispersed in light diffusion plate 120.

In surface light source device 100 according to the embodiment of the present invention, the light emitted from each light emitting element 220 is spread by light flux controlling member 300 so as to illuminate a wide range of light diffusion plate 120. The light reaching light diffusion plate 120 from each light flux controlling member 300 passes through light diffusion plate 120 while being diffused. Thus, surface light source device 100 according to the embodiment of the present invention can uniformly illuminate a planar illumination target member (for example, a liquid crystal panel).

Configuration of Light Flux Controlling Member

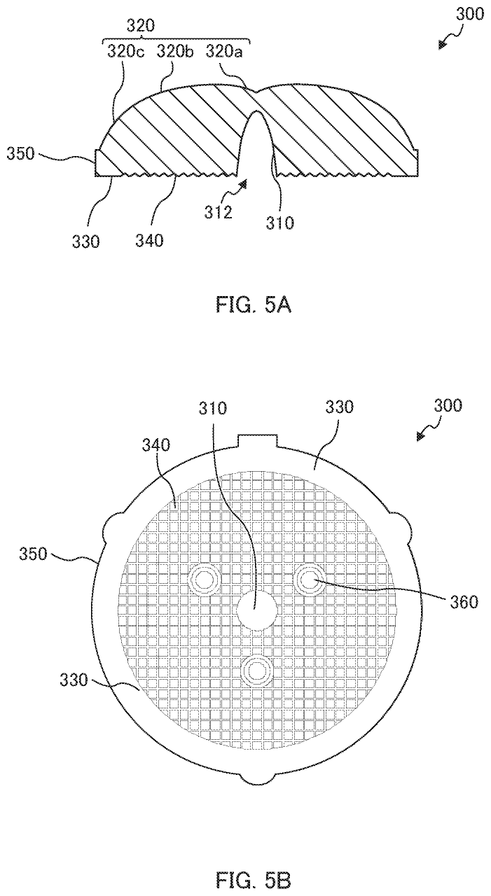

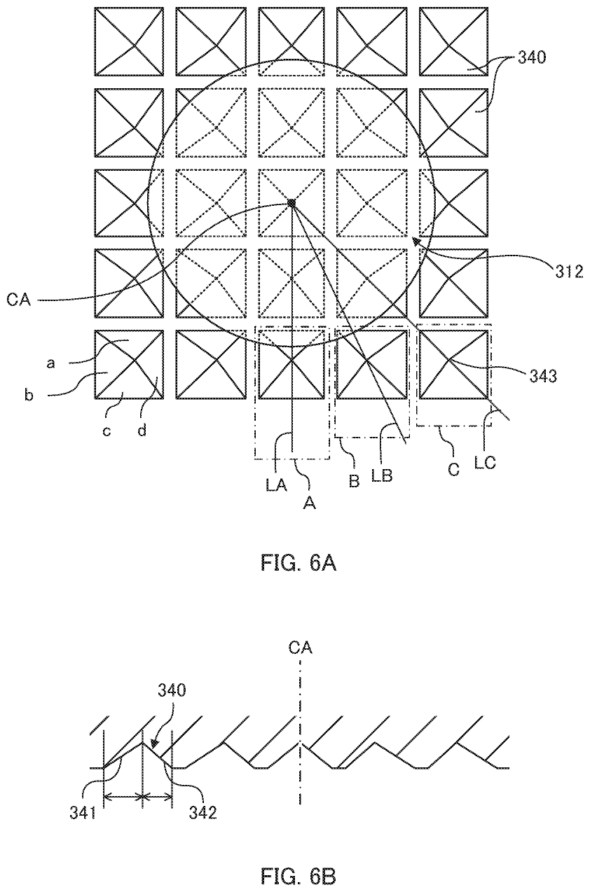

FIGS. 5A to 6B illustrate a configuration of light flux controlling member 300 according to Embodiment 1. FIG. 5A is a diagram of a cross section including central axis CA of light flux controlling member 300, and FIG. 5B is a bottom view. Note that leg part 360 is omitted in FIG. 5A.

As illustrated in FIG. 5A and FIG. 5B, light flux controlling member 300 includes incidence surface 310, emission surface 320, rear surface 330, and a plurality of first square pyramid parts 340. In addition, light flux controlling member 300 includes flange part 350 configured to ease the handling of light flux controlling member 300, and leg part 360 configured to define a gap for dissipating heat from light emitting element 220 to the outside, and to position and fix light flux controlling member 300 to substrate 210.

Incidence surface 310 enters, into light flux controlling member 300, a majority of the light emitted from light emitting element 220 while controlling the travelling direction of the light. Incidence surface 310 is an inner surface of recess 312 opening at rear surface 330. Recess 312 opens at a center portion of rear surface 330 so as to intersect central axis CA of light flux controlling member 300 (optical axis OA of light emitting element 220) (see FIG. 4). That is, incidence surface 310 is disposed so as to intersect central axis CA (optical axis OA). Incidence surface 310 intersects central axis CA of light flux controlling member 300, and is substantially rotationally symmetrical (in the present embodiment, circularly symmetrical) about central axis CA.

Emission surface 320 is disposed on the front side (light diffusion plate 120 side) of light flux controlling member 300. Emission surface 320 emits the light having entered light flux controlling member 300 to the outside while controlling the travelling direction of the light. Emission surface 320 intersects central axis CA, and is rotationally symmetrical (in the present embodiment, circularly symmetrical) about central axis CA.

Emission surface 320 includes first emission surface 320a located in a predetermined range around central axis CA, second emission surface 320b that is continuously formed at the periphery of first emission surface 320a, and third emission surface 320c that connects second emission surface 320b and flange part 350 (see FIG. 5A). First emission surface 320a is a curved surface protruding toward the rear side. Second emission surface 320b is a smooth curved surface located at the periphery of first emission surface 320a and protruding toward the front side. Second emission surface 320b has an annular protruding shape. Third emission surface 320c is a curved surface located at the periphery of second emission surface 320b.

Rear surface 330 is a plane extending from the edge of the opening of recess 312 in the radial direction on the rear side of light flux controlling member 300. A plurality of leg parts 360 and a plurality of first square pyramid parts 340 are disposed in rear surface 330.

FIG. 6A is a diagram for describing first square pyramid part 340, and FIG. 6B is a sectional view of first square pyramid part 340. Note that, in FIG. 6A, first square pyramid parts 340 are illustrated on the assumption that first square pyramid parts 340 are disposed also in the region where recess 312 is formed, and first square pyramid parts 340 located in recess 312 are illustrated by dotted lines. In FIG. 6B, first square pyramid parts 340 illustrated by dotted lines in FIG. 6A are also illustrated by solid lines.

First square pyramid part 340 includes first inclined surface 341 inclined so as to come closer to the rear side as the distance thereof from central axis CA increases, second inclined surface 342 inclined so as to come closer to the front side as the distance thereof from central axis CA increases, and connecting part 343 connecting first inclined surface 341 and second inclined surface 342. First square pyramid part 340 reflects, radially outward, a part of the light entered from incidence surface 310 and internally reflected by emission surface 320. The shape of first square pyramid part 340 is a substantially square pyramid shape corresponding to a space with a substantially rectangular bottom surface and one vertex connected with the four corners of the bottom surface with straight lines or curved lines, or a substantially truncated square pyramid shape that is a substantially square pyramid shape with a plane apex. In the present embodiment, first square pyramid part 340 has a substantially square pyramid shape.

In the case where first square pyramid part 340 has a substantially square pyramid shape, “connecting part” is the vertex connected with four side surfaces, and is the “center of the connecting part”. That is, connecting part 343 connects not only first inclined surface 341 and second inclined surface 342 described later, but also the other two side surfaces. In the case where first square pyramid part 340 has a substantially square pyramid shape, the side surfaces of first square pyramid part 340 may be flat surfaces, or curved surfaces. In addition, one side surface of first square pyramid part 340 may be composed of a plurality of surfaces. Also in this case, each of the plurality of surfaces may be a flat surface, or a curved surface. In addition, the boundary between two side surfaces adjacent to each other may be a clear ridgeline, or a curved round surface. Likewise, a portion near the vertex of the substantially square pyramid may have a round shape.

On the other hand, in the case where first square pyramid part 340 has a substantially truncated square pyramid shape, “connecting part” is the top surface of the substantially truncated square pyramid. In addition, the “center of the connecting part” is the center (gravity center) of the top surface. That is, connecting part 343 connects not only first inclined surface 341 and second inclined surface 342 described later, but also the other two side surfaces. In the case where first square pyramid part 340 has a substantially truncated square pyramid shape, the side surfaces of first square pyramid part 340 may be flat surfaces, or curved surfaces. In addition, one side surface of first square pyramid part 340 may be composed of a plurality of surfaces. Also in this case, each of the plurality of surfaces may be a flat surface, or a curved surface. In addition, the boundary between two side surfaces adjacent to each other may be a clear ridgeline, or a curved round surface. Likewise, the top surface of the substantially truncated square pyramid shape may be a flat surface, or a curved surface recessed toward the bottom surface side.

First square pyramid parts 340 may be disposed only in a part of rear surface 330, or may be disposed over the entirety of rear surface 330. In the present embodiment, first square pyramid parts 340 are disposed in a circular region of rear surface 330 excluding the outer periphery part of rear surface 330.

In addition, first square pyramid parts 340 are disposed in a lattice along a first direction orthogonal to central axis CA, and a second direction orthogonal to central axis CA and the first direction. Here, first square pyramid parts 340 are disposed such that each side of the bottom surface of each first square pyramid part 340 extends along the first direction or the second direction. Two first square pyramid parts 340 adjacent to each other in the first direction or the second direction may or may not be spaced away from each other. In the present embodiment, two first square pyramid parts 340 adjacent to each other in the first direction or the second direction are spaced from each other.

First square pyramid part 340 may protrude to the rear side from rear surface 330, or may be recessed to the front side from rear surface 330. In the present embodiment, first square pyramid part 340 is recessed to the front side from rear surface 330. In either case, each first square pyramid part 340 has four side surfaces. Here, of the four side surfaces, the surface inclined so as to come closer to the rear side as the distance thereof from central axis CA increases in the cross section including central axis CA is referred to as “first inclined surface 341”, and the surface inclined so as to come closer to the front side as the distance thereof from central axis CA increases in the cross section including central axis CA is referred to as “second inclined surface 342”. First inclined surface 341 is an inclined surface that reflects, in a radially outward direction of light flux controlling member 300, light internally reflected by emission surface 320 and reaching rear surface 330. Second inclined surface 342 is an inclined surface that reflects, toward the central axis side of light flux controlling member 300, light internally reflected by emission surface 320 and reaching rear surface 330.

Now, “first inclined surface 341” and “second inclined surface 342” are described in detail with reference to FIG. 6A and FIG. 6B. Note that, in each first square pyramid part 340 in FIG. 6A, the side surface located on the upper side in the drawing is referred to as “side surface a”, the side surface located on the left side in the drawing as “side surface b”, the side surface located on the lower side in the drawing as “side surface c”, and the side surface located on right side in the drawing as “side surface d”.

In each first square pyramid parts 340 in region A and region B surrounded by the dashed line in FIG. 6A, first inclined surface 341 is side surface c located on the side opposite to central axis CA. In addition, second inclined surface 342 is side surface a located on central axis CA side. That is, when cross sections LA and LB including central axis CA and the center of connecting part 343 are not aligned with the ridgeline between two side surfaces adjacent to each other, each of first inclined surface 341 and second inclined surface 342 is composed of a single side surface.

In first square pyramid part 340 in region C surrounded by the dashed line in FIG. 6A, first inclined surface 341 is surface c and side surface d located on the side opposite to central axis CA side. In addition, second inclined surface 342 is side surface a and side surface b located on the side opposite to surface c and side surface d. That is, when cross section LC including the central axis CA and the center of connecting part 343 includes the ridgeline between two side surfaces adjacent to each other, each of first inclined surface 341 and second inclined surface 342 is composed of two side surfaces.

In light flux controlling member 300 according to the present embodiment, each first square pyramid part 340 is recessed to the front side from rear surface 330, and, in each first square pyramid part 340, the center of connecting part 343 is located on central axis CA side with respect to the center (intersection of diagonal lines) of the bottom surface of the square pyramid. As a result, in each first square pyramid part 340, first inclined surface 341 that reflects, in a radially outward direction of light flux controlling member 300, the light reaching rear surface 330 from emission surface 320 is larger than second inclined surface 342 that reflects, toward the central axis side of light flux controlling member 300, the light reaching rear surface 330 from emission surface 320. With this configuration, in light flux controlling member 300 according to the present embodiment, light internally reflected by emission surface 320 and reaching rear surface 330 tends to be reflected in a radially outward direction of light flux controlling member 300.

Leg part 360 defines a gap for dissipating heat emitted from light emitting element 220 to the outside between substrate 210 and light flux controlling member 300, and sets the position of light flux controlling member 300 with respect to substrate 210. Leg part 360 may have any shape as long as the above-described functions can be ensured. In the present embodiment, leg part 360 has a substantially columnar shape. In addition, the number and position of leg part 360 may be set to any value. In the present embodiment, three leg parts 360 are disposed at even intervals in the circumferential direction.

### Modification 1

A surface light source device according to Modification 1 differs from the surface light source device according to Embodiment 1 only in the configuration of first square pyramid part 440 of light flux controlling member 400. In view of this, the components similar to those of surface light source device 100 are denoted with the same reference numerals and the description thereof will be omitted.

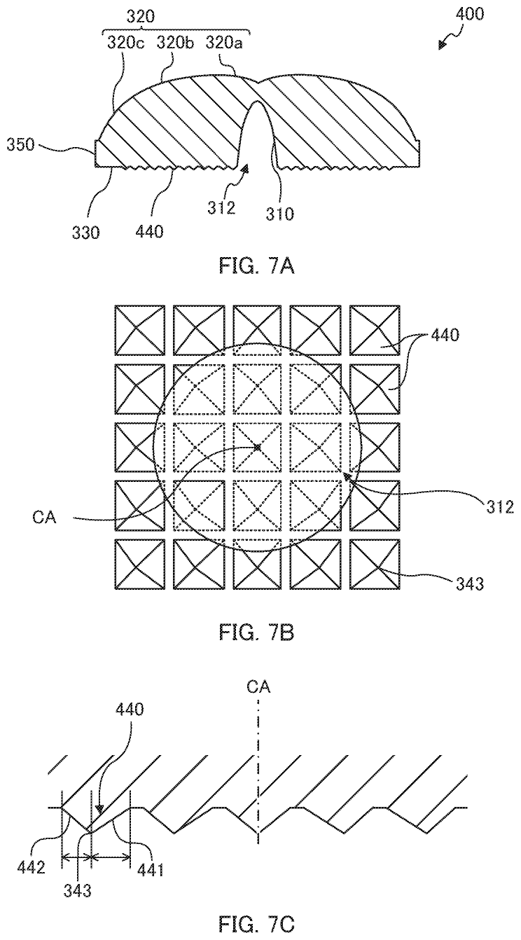

FIGS. 7A to 7C illustrate a configuration of light flux controlling member 400 according to Modification 1. FIG. 7A is a cross-sectional view including the central axis of light flux controlling member 400 according to Modification 1, FIG. 7B is a diagram for describing first square pyramid part 440 in light flux controlling member 400, and FIG. 7C is a partially enlarged sectional view of first square pyramid part 440. Note that FIG. 7B illustrates a plurality of first square pyramid parts 440 on the assumption that first square pyramid parts 440 are disposed also in a portion where recess 312 is formed, and first square pyramid parts 440 located in recess 312 are indicated with dotted lines. In addition, in FIG. 7C, first square pyramid parts 440 that are indicated with the dotted lines in FIG. 7B are also indicated with solid lines.

As illustrated in FIG. 7A, in light flux controlling member 400 according to Modification 1, each first square pyramid part 440 protrudes to the rear side from rear surface 330, and in each first square pyramid parts 440, the center of connecting part 343 is disposed outside the center (intersection of diagonal lines) of the bottom surface of the square pyramid in the radial direction of light flux controlling member 400. As a result, as illustrated in FIG. 7B and FIG. 7C, in each first square pyramid part 440, first inclined surface 441 that reflects, in a radially outward direction of light flux controlling member 400, the light reaching rear surface 330 from emission surface 320 is larger than second inclined surface 442 that reflects, toward the central axis side of light flux controlling member 300, the light reaching rear surface 330 from emission surface 320. In addition, the bottom portion of first square pyramid part 440 is disposed at a position further from central axis CA than the center of the bottom surface thereof. Accordingly, in light flux controlling member 400 according to Modification 1, light internally reflected by emission surface 320 and reaching rear surface 330 tends to be reflected in a radially outward direction of light flux controlling member 400.

### Modification 2

A surface light source device according to Modification 2 differs from the surface light source device according to Embodiment 1 only in the configuration of first square pyramid part 540 of light flux controlling member 500. In view of this, the components similar to those of surface light source device 100 are denoted with the same reference numerals and the description thereof will be omitted.

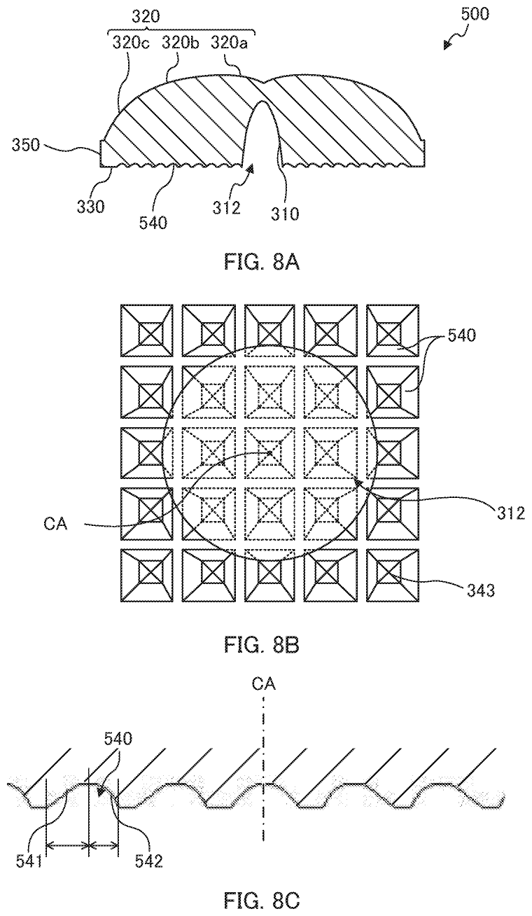

FIGS. 8A to 8C illustrate a configuration of light flux controlling member 500 according to Modification 2. FIG. 8A is a cross-sectional view including the central axis of light flux controlling member 500 according to Modification 2, FIG. 8B is a diagram for describing first square pyramid part 540 in light flux controlling member 500, and FIG. 8C is a partially enlarged sectional view of first square pyramid part 540. Note that, in FIG. 8B, a plurality of first square pyramid parts 540 are illustrated on the assumption that first square pyramid parts 540 are disposed also in a region where recess 312 is formed, and first square pyramid parts 540 located in recess 312 are indicated with dotted lines. In addition, in FIG. 8C, first square pyramid parts 540 that are indicated with the dotted lines in FIG. 8B are also indicated with solid lines.

As illustrated in FIG. 8A, in light flux controlling member 500 according to Modification 2, first square pyramid part 540 is recessed to the front side from rear surface 330, and in each first square pyramid part 540, the center of connecting part 343 is disposed on central axis CA side than the center (intersection of diagonal lines) of the bottom surface of the square pyramid. In addition, as illustrated in FIG. 8B and FIG. 8C, each of the four side surfaces of first square pyramid part 540 is composed of two curved surfaces. As a result, in each first square pyramid part 540, first inclined surface 541 that reflects, in a radially outward direction of light flux controlling member 500, the light reaching rear surface 330 from emission surface 320 is larger than second inclined surface 542 that reflects, toward the central axis side of light flux controlling member 500, the light reaching rear surface 330 from emission surface 320. Accordingly, in light flux controlling member 500 according to Modification 2, light internally reflected by emission surface 320 and reaching rear surface 330 tends to be reflected in a radially outward direction of light flux controlling member 500.

Note that, in light flux controlling member 500 according to Modification 2, first square pyramid part 540 may protrude to the rear side from rear surface 330. In this case, in each first square pyramid part 540, the center of connecting part 343 is disposed radially outside light flux controlling member 500 than the center (intersection of diagonal lines) of the bottom surface of the square pyramid.

### Effect

As described above, in surface light source device 100 according to the present embodiment, in first square pyramid part 340, 440 or 540 of light flux controlling member 300, 400 or 500, first inclined surface 341, 441 or 541 that reflects, in a radially outward direction of light flux controlling member 300, 400 or 500, the light reaching rear surface 330 from emission surface 320 is larger than second inclined surface 342, 442 or 542 that reflects, toward the central axis side of light flux controlling member 500, the light reaching rear surface 330 from emission surface 320. Accordingly, in surface light source device 100, a large part of light internally reflected by emission surface 320 in light flux controlling members 300, 400, and 500 is controlled to travel radially outward with respect to central axis CA, and thus luminance unevenness is less likely to be caused.

### Embodiment 2

A surface light source device according to Embodiment 2 differs from surface light source device 100 according to Embodiment 1 only in the configuration of light flux controlling member 600. In view of this, the components similar to surface light source device 100 are denoted with the same reference numerals and the description thereof will be omitted.

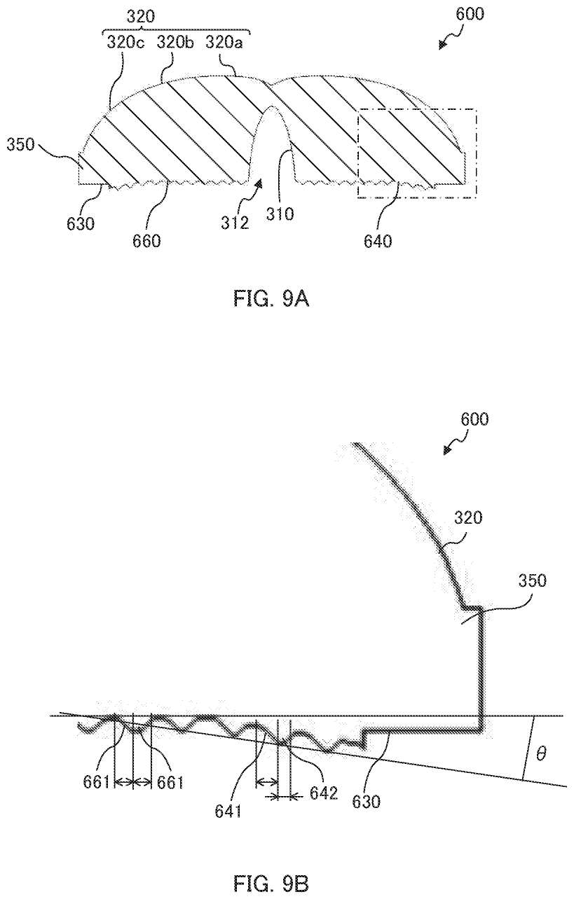

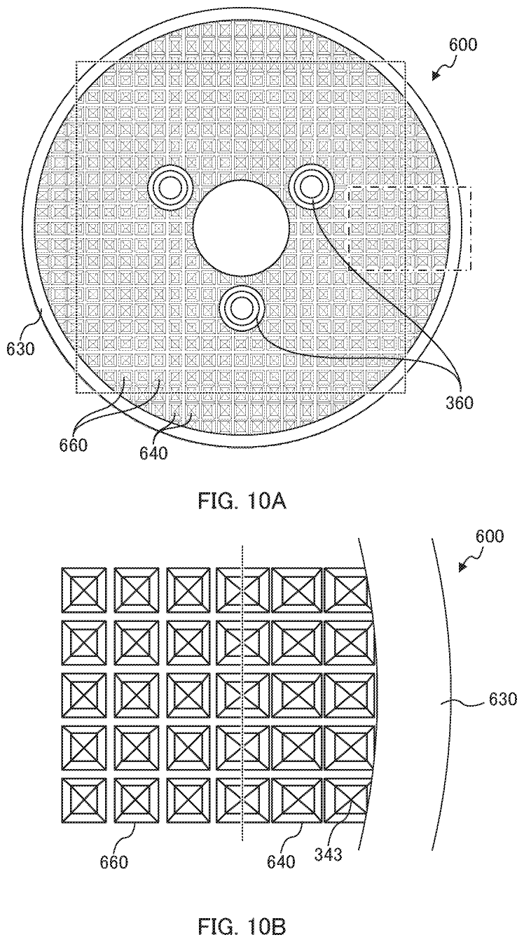

FIGS. 9A to 10B illustrate a configuration of light flux controlling member 600 according to Embodiment 2. FIG. 9A is a diagram of a cross section including central axis CA of light flux controlling member 600, and FIG. 9B is an enlarged view of a region surrounded by the dashed line in FIG. 9A. FIG. 10A is a bottom view of light flux controlling member 600, and FIG. 10B is an enlarged view of a region surrounded by the dashed line in FIG. 10A.

As illustrated in FIG. 9A to FIG. 10B, light flux controlling member 600 according to Embodiment 2 includes incidence surface 310, emission surface 320, rear surface 630, a plurality of first square pyramid parts 640, flange part 350, leg part 360, and a plurality of second square pyramid parts 660.

Rear surface 630 is disposed on the rear side of light flux controlling member 600, and extends in the radial direction from the opening edge of recess 312. A plurality of leg parts 360 and a plurality of second square pyramid parts 660 are disposed in a rectangular region on the center side of rear surface 630, and a plurality of first square pyramid parts 640 are disposed outside the rectangular region on rear surface 630.

The size of the rectangular region on the center side in rear surface 630 may be appropriately set. Preferably, the rectangular is larger than a rectangular inscribed in the outer edge of rear surface 630 and smaller than a rectangular circumscribed around the outer edge of rear surface 630.

A plane obtained by connecting the bottom surfaces of second square pyramid parts 660 is parallel to substrate 210. That is, the center portion of rear surface 630 is parallel to substrate 210. In contrast, a plane obtained by connecting the bottom surfaces of first square pyramid parts 640 approaches the front side as it comes closer to central axis CA. That is, the outer periphery part of rear surface 630 is inclined with respect to substrate 210. The inclination angle of the outer periphery part of rear surface 630 with respect to substrate 210 (rear surface 630) may be appropriately set. Preferably, inclination angle θ of the outer periphery part of rear surface 630 with respect to rear surface 630 falls within a range of 5° to 35°.

First square pyramid part 640 protrudes to the rear side from rear surface 630. The side surface of first square pyramid part 640 is composed of a plurality of curved surfaces, and connecting part 343 of two side surfaces adjacent to each other is a curved round surface. First square pyramid part 640 includes first inclined surface 641 and second inclined surface 642. In the cross section including central axis CA, first inclined surface 641 is inclined so as to come closer to the rear side as the distance thereof from central axis CA increases, and second inclined surface 642 is inclined so as to come closer to the rear side as the distance thereof from central axis CA increases. First inclined surface 641 is an inclined surface that reflects, in a radially outward direction of light flux controlling member 600, the light internally reflected by emission surface 320 and reaching rear surface 630. Second inclined surface 642 is an inclined surface that reflects, toward the central axis side of light flux controlling member 600, the light internally reflected by emission surface 320 and reaching rear surface 630. Note that, in the present embodiment, the inclination angles of first inclined surface 641 and second inclined surface 642 with respect to central axis CA are identical to each other unlike Embodiment 1.

In the outer periphery part of rear surface 630, first square pyramid parts 640 are disposed in a lattice along a first direction orthogonal to central axis CA, and a second direction orthogonal to central axis CA and the first direction. Here, first square pyramid parts 640 are disposed such that each side of the bottom surface of each first square pyramid part 640 extends along the first direction or the second direction. Two first square pyramid parts 640 adjacent to each other in the first direction or the second direction may or may not be spaced away from each other. In the present embodiment, two second square pyramid parts 660 adjacent to each other in the first direction or the second direction are spaced from each other. The majority of light internally reflected by emission surface 320 reaches the outer periphery part of rear surface 630 where first square pyramid parts 640 are disposed. With this configuration, the light internally reflected by emission surface 320 can be efficiently reflected radially outward with respect to central axis CA.

As illustrated in FIG. 10A, light flux controlling member 600 according to the present embodiment does not include first square pyramid part 640 whose diagonals on the bottom surface is parallel to the line including central axis CA and the center of connecting part 343 (see first square pyramid part 340 in region C of FIG. 6A). With this configuration, in each first square pyramid part 640, first inclined surface 641 is composed of a single side surface closest to central axis CA, and second inclined surface 642 is composed of a side surface located on the side opposite to first inclined surface 641.

In addition, as described above, a surface obtained by connecting bottom surfaces of a plurality of first square pyramid parts 640 is inclined such that the surface comes closer to the rear side as the distance thereof from central axis CA increases. With this configuration, first inclined surface 641 is larger than second inclined surface 642. In addition, in plan view of first square pyramid part 640, the center of connecting part 343 is located at a position farther from central axis CA than the center of the bottom surface thereof.

Second square pyramid part 660 includes a third inclined surface inclined so as to come closer to the rear side as the distance thereof from central axis CA increases, and a fourth inclined surface inclined so as to come closer to the front side as the distance thereof from central axis CA increases. Second square pyramid part 660 internally reflects a part of the light entered from incidence surface 310 and internally reflected by emission surface 320. The shape of second square pyramid part 660 is a substantially square pyramid shape corresponding to a space with a substantially rectangular bottom surface and one vertex connected with the four corners of the bottom surface with straight lines or curved lines, or a substantially truncated square pyramid shape that is a substantially square pyramid shape with a plane apex. In the present embodiment, second square pyramid part 660 has a substantially square pyramid shape.

In the case where second square pyramid part 660 has a substantially square pyramid shape, side surface 661 of second square pyramid part 660 may be a flat surface or a curved surface. In addition, a single side surface 661 of second square pyramid part 660 may be composed of a plurality of surfaces. Also in this case, each of the plurality of surfaces may be a flat surface, or a curved surface. In the present embodiment, each side surface 661 of second square pyramid part 660 is composed of two surfaces. In addition, the boundary between two side surfaces 661 adjacent to each other may be a clear ridgeline, or a curved round surface. Likewise, a portion near the vertex of the substantially square pyramid may have a round shape.

In the case where second square pyramid part 660 has a substantially truncated square pyramid shape, the side surface of second square pyramid part 660 may be a flat surface or a curved surface. Connecting part 343 connects not only third inclined surface and fourth inclined surface, but also the other two side surfaces 661. In addition, a single side surface of second square pyramid part 660 may be composed of a plurality of surfaces. Also in this case, each of the plurality of surfaces may be a flat surface, or a curved surface. In addition, the boundary between two side surfaces adjacent to each other may be a clear ridgeline, or a curved round surface. Likewise, the top surface of the substantially truncated square pyramid shape may be a flat surface, or a curved surface recessed toward the bottom surface side.

A plurality of second square pyramid parts 660 are disposed in a lattice along the first direction and the second direction. Here, a plurality of second square pyramid parts 660 are disposed such that each side of the bottom surface of each second square pyramid part 660 extends along the first direction or the second direction. Two second square pyramid parts 660 adjacent to each other in the first direction or the second direction may or may not be spaced away from each other. In the present embodiment, two second square pyramid parts 660 adjacent to each other in the first direction or the second direction are spaced from each other.

Second square pyramid part 660 may protrude to the rear side from rear surface 630, or recessed to the front side from rear surface 630. In the present embodiment, second square pyramid part 660 is recessed to the front side from rear surface 630. In either case, each second square pyramid part 660 includes four side surfaces 661. In plan view, in each second square pyramid part 660, the center (gravity center) of connecting part 343 is located at the center (intersection of diagonal lines) of the bottom surface of the square pyramid. Unlike first square pyramid part 640, the four side surfaces 661 of second square pyramid part 660 have the same size.

Note that first square pyramid part 640 may be recessed to the front side from rear surface 630. In this case, in plan view of first square pyramid part 640, the center of connecting part 343 is closer to central axis CA than the center of its bottom surface.

### Effect

The surface light source device according to the present embodiment provides the effect same as that of Embodiment 1.

Note that, the side surfaces of first square pyramid parts 340, 440, 540 and 640 and side surface 661 of second square pyramid part 660 may be roughened. With this configuration, the light reaching first inclined surfaces 341, 441, 541 and 641 and second inclined surfaces 342, 442, 542 and 642 can be diffused, and luminance unevenness due to light internally reflected by emission surface 320 can be further reduced.

This application is entitled to and claims the benefit of Japanese Patent Application No. 2017-009401 filed on Jan. 23, 2017, the disclosure each of which including the specification, drawings and abstract is incorporated herein by reference in its entirety.

### INDUSTRIAL APPLICABILITY

The light flux controlling member, the light emitting device and the surface light source device according to the embodiments of the present invention are applicable to, for example, a backlight of liquid crystal display apparatuses or generally-used illumination apparatuses.

### REFERENCE SIGNS LIST

10, 20 Light emitting device
11 Light emitting element
12, 22 Light flux controlling member
13 Incidence surface
14 Reflection surface
15 Rear surface
16 Substrate
27 Inclined surface
28 Inclined surface
29 Recess
100 Surface light source device
100′ Display device
107 Display member
110 Housing
112 Bottom plate
114 Top plate
120 Light diffusion plate
200 Light emitting device
210 Substrate
220 Light emitting element
300, 400, 500, 600 Light flux controlling member
310 Incidence surface
312 Recess
320 Emission surface
320a First emission surface
320b Second emission surface
320c Third emission surface
330, 630 Rear surface
340, 440, 540, 640 First square pyramid part
341, 441, 541, 641 First inclined surface
342, 442, 542, 642 Second inclined surface
343 Connecting part
350 Flange part
360 Leg part
660 Second square pyramid part
66a Single side surface
a, b, c, d Side surface
CA Central axis of light flux controlling member
OA Optical axis of light emitting element

1. A light flux controlling member configured to control a distribution of light emitted from a light emitting element, the light flux controlling member comprising:
an incidence surface that is an inner surface of a recess having an opening on a rear side at a position intersecting a central axis of the light flux controlling member, the incidence surface being configured to allow incidence of light emitted from the light emitting element;
an emission surface formed on a front side at a position intersecting a central axis of the light flux controlling member, the emission surface being configured to emit, to outside, the light entered from the incidence surface;
a rear surface formed surrounding the opening of the recess; and
a plurality of first square pyramid parts disposed in a lattice in at least a part of the rear surface, each of the plurality of first square pyramid parts having a substantially square pyramid shape or a substantially truncated square pyramid shape protruding to the rear side from the rear surface, or recessed to the front side from the rear surface,
wherein each of the plurality of first square pyramid parts includes a first inclined surface, a second inclined surface and a connecting part, the first inclined surface being inclined such that the first inclined surface comes closer to the rear side as a distance thereof from the central axis increases, the second inclined surface being inclined such that the second inclined surface comes closer to the front side as a distance thereof from the central axis increases, the connecting part connecting the first inclined surface and the second inclined surface, and
wherein in each of the plurality of first square pyramid parts, the first inclined surface is larger than the second inclined surface in a cross section including the central axis and a center of the connecting part.

2. The light flux controlling member according to claim 1,
wherein each of the plurality of first square pyramid parts protrudes to the rear side from the rear surface; and
wherein, in each of the plurality of first square pyramid parts, the center of the connecting part is farther from the central axis than a center of a bottom surface of the each of the plurality of first square pyramid parts.

3. The light flux controlling member according to claim 1,
wherein each of the plurality of first square pyramid parts is recessed to the front side from the rear surface; and
wherein, in each of the plurality of first square pyramid parts, the center of the connecting part is closer to the central axis than a center of a bottom surface of the each of the plurality of first square pyramid parts.

4. The light flux controlling member according to claim 1, further comprising
a plurality of second square pyramid parts disposed in a lattice in the rear surface in a region where the plurality of first square pyramid parts are not disposed, each of the plurality of second square pyramid parts having a substantially square pyramid shape or a substantially truncated square pyramid shape protruding to the rear side from the rear surface, or recessed to the front side from the rear surface,
wherein each of the plurality of second square pyramid parts includes a third inclined surface and a fourth inclined surface, the third inclined surface being inclined such that the third inclined surface comes closer to the rear side as a distance thereof from the central axis increases, the fourth inclined surface being inclined such that the fourth inclined surface comes closer to the front side as a distance thereof from the central axis increases, and
wherein sizes of the third inclined surface and the fourth inclined surface are identical to each other in a cross section including the central axis.

5. The light flux controlling member according to claim 4,
wherein the plurality of first square pyramid parts are disposed outside a region surrounded by a rectangular including the recess of the rear surface, and
wherein the plurality of second square pyramid parts are disposed in the region surrounded by the rectangular.

6. The light flux controlling member according to claim 1, wherein a side surface of each of the plurality of first square pyramid parts is roughened.

7. The light flux controlling member according to claim 4, wherein a side surface of each of the plurality of second square pyramid parts is roughened.

8. A light emitting device comprising:
a light emitting element; and
the light flux controlling member according to claim 1 that is disposed such that the central axis coincides with an optical axis of the light emitting element.

9. A surface light source device, comprising:
the light emitting device according to claim 8; and
a light diffusion member configured to allow light from the light emitting device to pass therethrough while diffusing the light.

10. A display device, comprising:
the surface light source device according to claim 9; and
a display member configured to be irradiated with light emitted from the surface light source device.
